(19) United States
(12) Patent Application Publication
(10) Pub. No.: US 2009/0122174 A1
(43) Pub. Date: May 14, 2009

(54) SOLID-STATE IMAGING DEVICE AND METHOD OF DRIVING THE SAME

(75) Inventor: Takatoshi KANO, Toyama (JP)

Correspondence Address: HAMRE, SCHUMANN, MUELLER & LARSON P.C., P.O. BOX 2902-0902, MINNEAPOLIS, MN, 55402, US

(73) Assignee: Panasonic Corporation, Osaka (JP)

(21) Appl. No.: 12/264,470

(22) Filed: Nov. 4, 2008

(30) Foreign Application Priority Data
Nov. 9, 2007 (JP) 2007-292387

(51) Int. Cl. H04N 5/335

(52) U.S. Cl. 348/308

(57) ABSTRACT

A solid-state imaging device includes: an effective pixel area in which a plurality of pixels having photodiodes (PD) are provided in row and column directions, the effective pixel area being capable of allowing light from outside to be incident in each PD and generating electric signals by photoelectric conversion; and a non-effective pixel area in which a plurality of pixels covered with a light-shielding film are provided, and a reference area and a failure-detection pattern area are formed as sub-areas. Each pixel in the reference area has a PD. The failure-detection pattern area has a configuration such that pixels with PD and pixels without PD are arranged in combination in a predetermined arrangement pattern. Each of pixels in the effective pixel area is driven so as to output a pixel signal, and each of pixels in the non-effective pixel area including the failure-detection pattern area also can be driven so as to output a pixel signal. A failure such that a signal from an image sensor is not outputted at all can be detected even in a dark environment.

### TECHNICAL FIELD

The present invention relates to a MOS-type solid-state imaging device. The present invention particularly relates to a solid-state imaging device having a mechanism that is capable of determining whether there is no incident light or the device has a failure, even under dark conditions without incidence of external light, thereby ensuring failsafe; and a method for driving the solid-state imaging device.

### BACKGROUND ART

FIG. 6 is a schematic view showing a configuration of a pixel area (photo-detecting area) 2 and a signal processing area 4 provided in a solid-state imaging device 1. In the pixel area 2, pixel cells 5 including photodiodes are arrayed in row and column directions. In the signal processing area 4, processing circuits for processing signals read out of the pixel cells 5 via vertical signal lines 7 are provided; and noise canceling circuits 6 are also provided in the foregoing area. Image signals processed in the signal processing area 4 are outputted to the outside via a horizontal signal line 8.

The pixel area 2 is divided broadly into an effective pixel area 3 encircled by an inner broken line, and a non-effective pixel area 20 between an outer broken line and the inner broken line. The non-effective pixel area 20 is provided in order to generate reference signals for image signal levels outputted from the pixel cells 5 composing the effective pixel area 3. The pixel cells 5 of the effective pixel area 3 are structured so as to output electric signals corresponding to the amounts of light incident in the photodiodes, while the pixel cells 5 in the non-effective pixel area 20 are structured so that light is prevented from being incident in the photodiodes by a light-shielding film (this is implied by hatching), whereby the pixel cells 5 output optical black signals. The effective pixel area 3 and the non-effective pixel area 20 have no structural difference therebetween, except for the presence/absence of the light-shielding film.

FIG. 7 shows an example of a concrete circuit diagram of the pixel cell 5 shown in FIG. 6. Each pixel cell 5 includes a photodiode 9, a transfer gate 10, a floating diffusion (FD) 11, a reset transistor 13 having a reset gate 12, an amplifier transistor 15 having an amplifier gate 14, and a capacitor 16. The transfer gate 10 is connected to a TRANS signal line 18 for supplying a TRANS signal, and the reset gate 12 is connected to a RSCELL signal line 17 for supplying a RSCELL signal. The amplifier transistor 15 is connected between a power source VDD line 19 for supplying a VDD voltage, and the vertical line 7.

The solid-state imaging device is driven in a manner as shown in a timing chart of FIG. 8. More specifically, before an operation of reading image data accumulated in the photodiode 9, the RSCELL signal becomes High “H” at a timing (a), whereby the reset transistor 13 is controlled so as to be turned ON. This causes the FD 11 to have a potential of Eᵣₑₛₑₜ, which provides a reading-standby state. When in this state the TRANS signal voltage “H” is applied to the transfer gate 10 at a timing (b), photoelectrons obtained by photoelectric conversion by the photodiode 9 are transferred to the FD 11. This causes the potential of the FD 11 to be reduced to a level corresponding to an amount of charges accumulated in the photodiode 9, thereby becoming E_{sig} at a timing (c). The potential of the FD 11 is applied to the amplifier gate 14. On the vertical signal line 7, a voltage signal appears that has a magnitude obtained by transformation of the power source voltage VDD by the amplifier transistor 15 according to the level of the potential of the amplifier gate 14. Finally, the power source voltage VDD is caused to be reduced to a Low level “L” at a timing (d), whereby the reset transistor 13 is controlled to assume an ON state. This causes the potential of the FD 11 to be reduced to a level of Eₙ, which provides a non-selection state.

In recent years, however, product application fields in which CCD-type or MOS-type solid-state imaging devices are used have expanded, and such products are installed in automobiles so as to be used for monitoring the inside and outside thereof. Such a solid-state imaging device to be installed in a vehicle, and a camera system incorporating such a solid-state imaging device, have a higher possibility of risking a user's life in the event of failure, as compared with a conventional digital camera or video camera for consumer use. Therefore, the system itself is required to have high reliability, and is required indispensably to have a mechanism that provides failsafe even in the event of failure.

On the other hand, JP 2003-234966 A shows a solid-state imaging device configured as follows: a plurality of apertures in a specific arrangement pattern are provided in a part of the light-shielding film that blocks light from the outside, in the non-effective pixel area 20 in the solid-state imaging device shown in FIG. 6, and information corresponding to the plural-aperture arrangement pattern is outputted as a part of an imaging signal. More specifically, for every readout operation from the pixel cells 5 in the effective pixel area 3, not only a signal from the effective pixel area 3, but also a signal corresponding to the foregoing specific arrangement pattern from the pixel cells 5 in the non-effective pixel area 20, are read out, so that an imaging signal of each frame should output information according to the specific arrangement pattern at all the times.

This configuration according to JP 2003-234966 A is intended to use a video signal generated according to a specific arrangement pattern as a serial number, and causing a video output signal to contain this serial number information, so as to identify an individual solid-state imaging element. Therefore, a specific arrangement pattern in this case is not intended to provide a mechanism for a failsafe function.

A usual camera system outputs, to the outside, only a signal corresponding to an amount of light incident in photodiodes formed in an effective pixel area of a solid-state imaging device. Therefore, there is a problem that when no signal is outputted at all from an image sensor owing to a failure, it cannot be distinguished whether it is caused by a failure, or it is caused by dark conditions without incidence of light on photodiodes. As a result, in the event of failure, it is impossible to detect it as a failure, and the device cannot be used as a vehicle-installed device, which is required to have a completely reliable failsafe function indispensably.

As a method for achieving the failsafe, it might be suggested to use a method disclosed in JP 2003-234966 A. Information of a specific pattern, however, is dependent on an amount of light that is incident, via light-shielding film apertures formed in a specific arrangement pattern in the non-effective pixel area 20, in the photodiodes of the pixel cells 5 below the film. Therefore, under dark conditions such as night driving conditions in which no charge is accumulated in the photodiodes in the specific pattern, the information of the specific pattern is not outputted. Therefore, even though the image sensor works normally, the information of the specific pattern is not outputted in some cases. Thus, the presence/absence of a signal of the specific pattern cannot be used for detecting the presence/absence of a failure.

### DISCLOSURE OF THE INVENTION

Therefore, with a view to solving the above-described problems, it is an object of the present invention to provide a solid-state imaging device that is capable of detecting a failure such that a signal from an image sensor is not outputted at all, even in a dark environment, for example, under night driving conditions.

A solid-state imaging device of the present invention includes: an effective pixel area in which a plurality of pixels having photodiodes (PD) are provided in row and column directions, the effective pixel area being capable of allowing light from the outside to be incident in each photodiode and generating electric signals by photoelectric conversion; and a non-effective pixel area in which a plurality of pixels covered by a light-shielding film are provided, and a reference area and a failure-detection pattern area are formed as sub-areas. In the solid-state imaging device, each of pixels in the reference area has a photodiode, and the failure-detection pattern area has a configuration such that pixels without PD in which a photodiode is provided and pixels without PD in which a photodiode is not provided are arranged in combination in a predetermined arrangement pattern. The solid-state imaging device is configured so that each of the pixels in the effective pixel area is driven so as to output a pixel signal, and each pixel in the non-effective pixel area including the failure-detection pattern area also can be driven so as to output a pixel signal.

With the present invention, since an output signal according to the arrangement pattern of the pixels with PD and the pixels without PD can be obtained, a failure such that a signal from an image sensor is not outputted at all can be detected even in a dark environment, whereby a failsafe function can be provided.

### BRIEF DESCRIPTION OF THE DRAWINGS

FIG. 1 is a plan view showing a schematic configuration of a solid-state imaging device according to an embodiment of the present invention.

FIG. 2 shows a layout of a pixel area in the solid-state imaging device.

FIG. 3A is a cross-sectional view showing a pixel with PD in which a photodiode is provided, in the solid-state imaging device.

FIG. 3B is a cross-sectional view showing a pixel without PD in which a photodiode is not provided, in the solid-state imaging device.

FIG. 4 is an equivalent circuit diagram of a pixel without PD in the solid-state imaging device.

FIG. 5 is a control timing chart for driving a pixel in a failure-detection pattern area according to the present invention.

FIG. 6 is a plan view showing a schematic configuration of a conventional exemplary solid-state imaging device.

FIG. 7 is an equivalent circuit diagram of a pixel with PD in the conventional exemplary solid-state imaging device.

FIG. 8 is a control timing chart for driving a pixel in the conventional exemplary solid-state imaging device.

### DESCRIPTION OF THE INVENTION

The present invention may have the following variations based on the above-described configuration.

Specifically, in the solid-state imaging device of the present invention, the failure-detection pattern area may be configured by arranging the pixels with PD and the pixels without PD in a row.

Further, the solid-state imaging device may be configured so that the pixel in the effective pixel area includes: the photodiode, which can carry out photoelectric conversion of incident light and accumulate the charges obtained; a floating diffusion in which charges are accumulated temporarily; a transfer transistor that transfers charges in the photodiode to the floating diffusion; a reset transistor that resets charges in the floating diffusion; and an amplifier transistor that amplifies a potential of the floating diffusion, the pixel disposed in the reference area and the pixel with PD disposed in the failure-detection pattern area have the same configuration as that of the pixel in the effective pixel area, and the pixel without PD disposed in the failure-detection pattern area includes the floating diffusion, the reset transistor, and the amplifier transistor.

A method for driving a solid-state imaging device according to the present invention is a method for driving the solid-state imaging device of the above-described basic configuration, which includes: a step (1) of reading image signals from the pixels in the effective pixel area; a step (2) of carrying out an operation for injecting charges from the outside into the pixels in the failure-detection pattern area; and then, a step (3) of reading signals according to the injected charges from each of pixels in the failure-detection patter area.

This driving method can be applied to a solid-state imaging device having the following configuration: the pixel in the effective pixel area includes: the photodiode, which can carry out photoelectric conversion of incident light and accumulate the charges obtained; a floating diffusion in which charges are accumulated temporarily; a transfer transistor that transfers charges of the photodiode to the floating diffusion; a reset transistor that resets charges in the floating diffusion; and an amplifier transistor that amplifies a potential of the floating diffusion, the pixel disposed in the reference area and the pixel with PD disposed in the failure-detection pattern area have the same configuration as that of the pixel in the effective pixel area, and the pixel without PD disposed in the failure-detection pattern area includes the floating diffusion, the reset transistor, and the amplifier transistor.

In this case, preferably, the step (2) includes: a sub-step (2a) of controlling the reset transistor and the transfer transistor of the pixels in the failure-detection pattern area to be an ON state so as to inject charges into the floating diffusion and the photodiode via the reset transistor and the transfer transistor with use of a power source voltage; and a sub-step (2b) of controlling the transfer transistor to be OFF state and subsequently controlling the reset transistor to be ON state so as to reset a potential of the floating diffusion.

In the foregoing driving method, preferably, in the sub-step (2a), the power source voltage is lower than any voltage used when pixel signals are read from the effective pixel area.

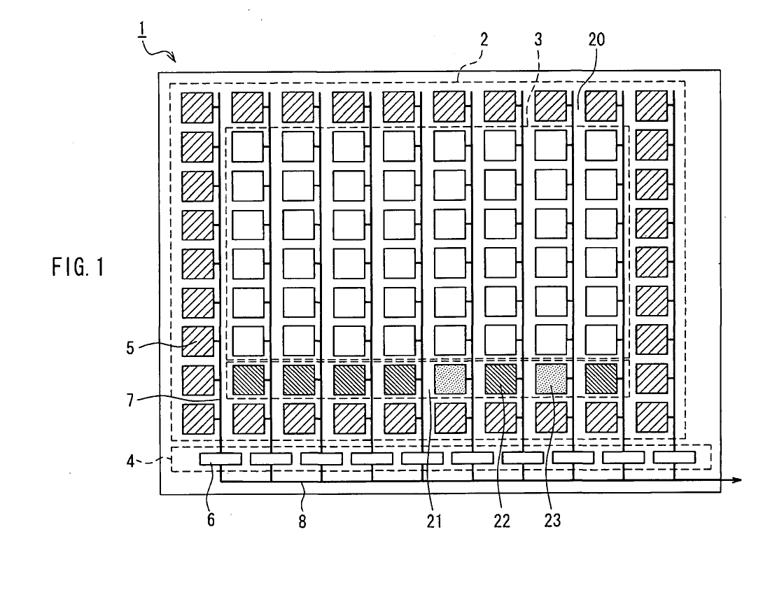

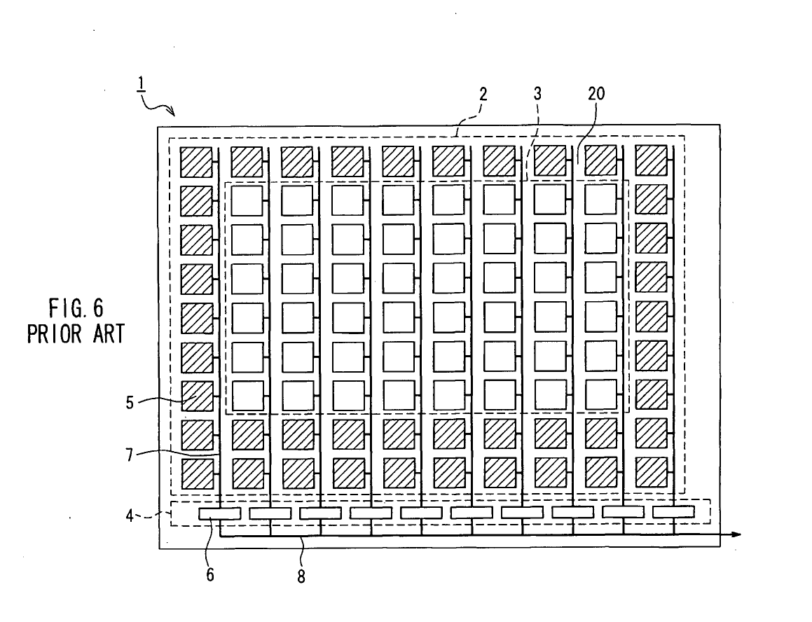

The following describes a solid-state imaging device and a method for driving the same according to an embodiment of the present invention in detail, while referring to the drawings. FIG. 1 is a schematic view showing a configuration of a solid-state imaging device according to the present embodiment. In the following description, the same elements as those in the conventional exemplary solid-state imaging device shown in FIG. 6 are designated with the same reference numerals.

A solid-state imaging device 1 includes a pixel area (photo-detecting area) 2 and a signal processing area 4. In the pixel area 2, pixel cells 5 provided with photodiodes are arrayed in row and column directions. The pixel area 2 is divided broadly into an effective pixel area 3 in a range encircled by an innermost broken line, and a non-effective pixel area 20 indicated by hatching, in a range around the effective pixel area 3, encircled by an outermost broken line. In the signal processing area 4, processing circuits for processing signals read out of the pixel cells 5 via vertical signal lines 7 are provided, irrespective of the effective pixel area 3 or the non-effective pixel area 20; and the area also includes noise canceling circuits 6. Image signals processed by the signal processing area 4 are outputted to the outside via a horizontal signal line 8.

The non-effective pixel area 20 includes the following areas as sub-areas: a reference area for generating a signal to be used as a reference for an image signal level outputted by the pixel cell 5 constituting the effective pixel area 3, as is the case with the conventional example; and a failure-detection pattern area 21 which is indicated by hatching different from the reference area.

The pixel cell 5 of the effective pixel area 3 outputs an electric signal corresponding to an amount of light incident in a photodiode, while the pixel cell 5 in the reference area of the non-effective pixel area 20 is configured so that light is not incident in the photodiode because of a light-shielding film, and hence, it outputs an optical black signal. The failure-detection pattern area 21 is provided by changing a specific one row in the non-effective pixel area 20. In this area, pixels 22 with PD, in each of which a photodiode (PD) is provided in the usual manner, and pixels 23 without PD, in each of which no PD is provided, are formed in a specific arrangement pattern.

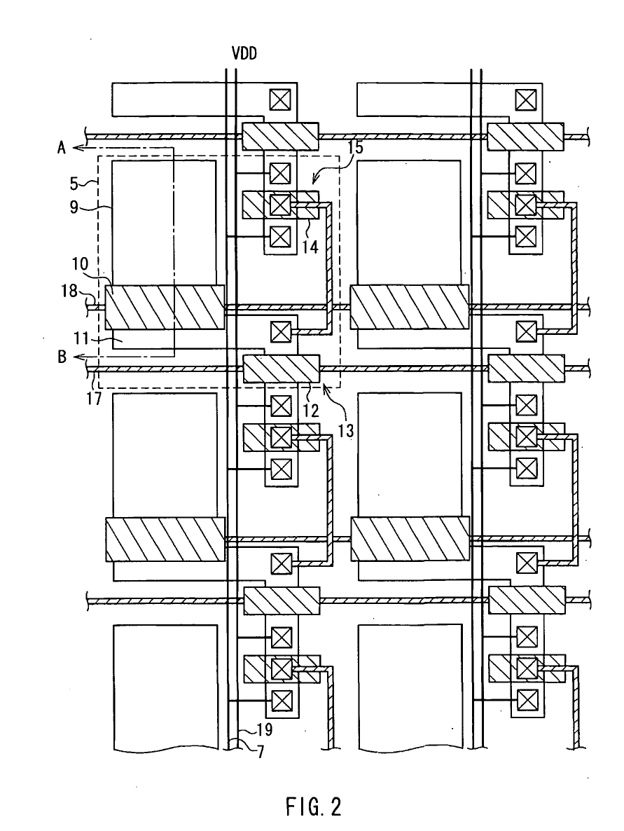

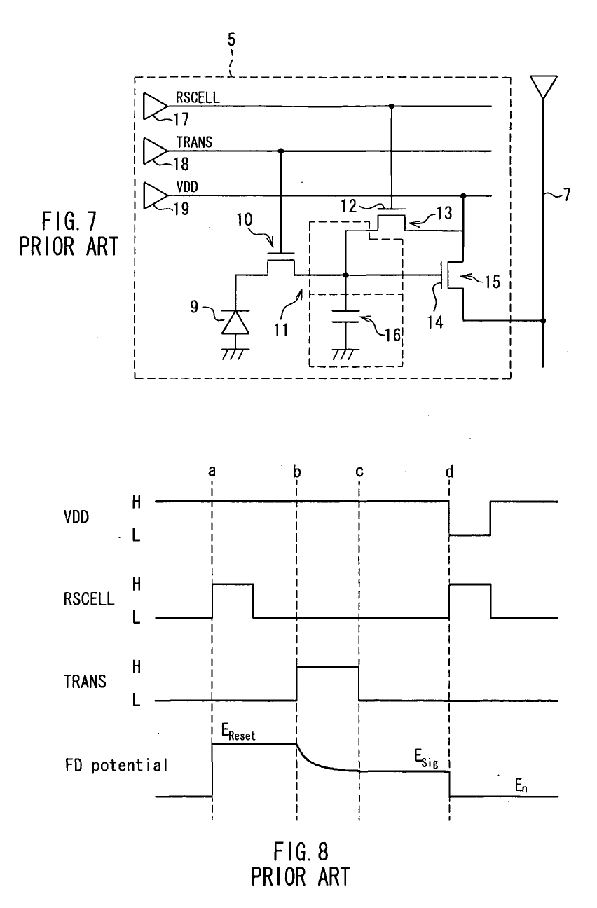

FIG. 2 is a plan view showing a specific pattern layout of the pixel area in the solid-state imaging device having the above-described configuration. This pattern layout corresponds to the same configuration as that of the circuit shown in FIG. 7. Both of the effective pixel area 3 and the non-effective pixel area 20 basically have the same layout, but specific pixel cells in the failure-detection pattern area 21 have a different pattern layout, as will be described later. Further, though not shown in FIG. 2, the non-effective pixel region 20 fully is covered with a light-shielding film.

In FIG. 2, an area encircled by a broken line for indicating the pixel cell 5 corresponds to one pixel cell, in which a photodiode 9, a transfer gate 10 of a transfer transistor, an amplifier gate 14 of an amplifier transistor 15, a FD 11, and a reset gate 12 of a reset transistor 13 are formed. These elements are connected mainly with the use of aluminum wiring lines, according to the circuit configuration shown in FIG. 7. Vertical signal lines 7, RSCELL signal lines 17, TRANS signal lines 18, and power source VDD lines 19 are connected with corresponding elements in the pixel cells 5, respectively.

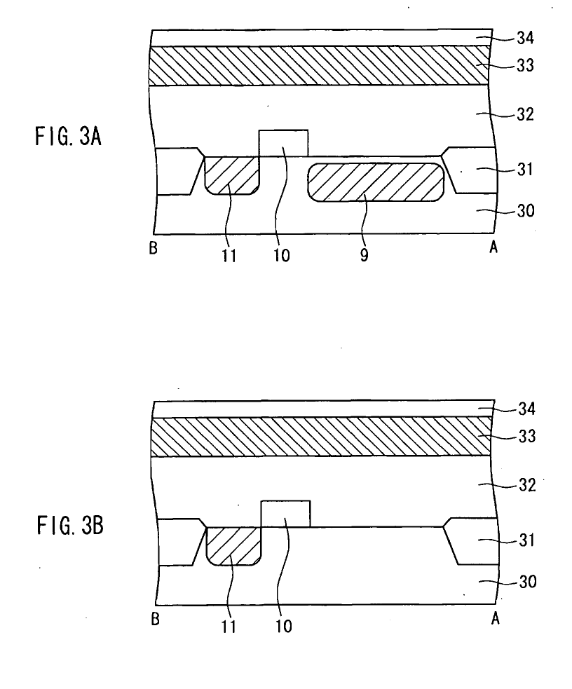

FIGS. 3A and 3B are cross-sectional views taken along a line A-B in FIG. 2, which show cross-sectional structures of the pixels in the failure-detection pattern area 21. FIG. 3A shows a cross section of the pixel 22 with PD (see FIG. 1) in which a photodiode is formed in the usual manner, and FIG. 3B shows a cross section of the pixel 23 without PD in which a photodiode is not formed.

In the pixel 22 with PD shown in FIG. 3A, the photodiode 9 and the FD 11, which are second-conductivity-type wells, as well as an element separation region 31, are formed in a first-conductivity-type silicon substrate 30. Besides, the transfer gate 10 is formed between the photodiode 9 and the FD 11, on the substrate 30. Above the photodiode 9, the FD 11, and the transfer gate 10, an interlayer insulation film 32 made of a silicon oxide film, a light-shielding film 33 made of a metal such as aluminum, for example, and a sealing film 34 made of a silicone nitride film are formed in the stated order from the silicon substrate 30. The light-shielding film 33 does not have an aperture even above the photodiode 9. An equivalent circuit of the pixel 22 with PD has a circuit configuration as shown in FIG. 7.

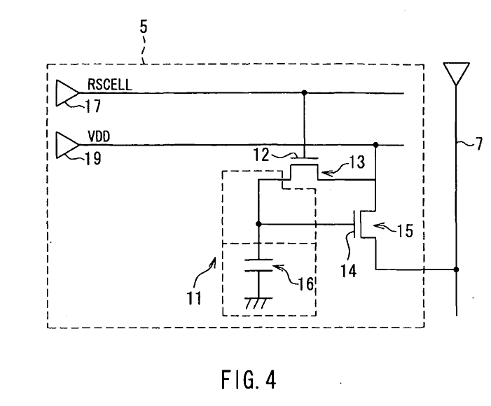

On the other hand, the structure of the pixel 23 without PD shown in FIG. 3B is similar to the structure of the pixel 22 with PD shown in FIG. 3A except that the photodiode 9 is not formed in the pixel 23 without PD. Alternatively, the pixel 23 without PD may be configured so that the transfer gate 10 also may be omitted from the circuit, as shown in FIG. 4.

As described above, as to the specific one row in the non-effective pixel area 20, the pixels 22 with PD shown in FIG. 3A and the pixel 23 without PD shown in FIG. 3B are arranged in a specific array. The pixel 23 without PD is formed by, for example, masking, so that an impurity needed for forming a photodiode is prevented from being injected. An arrangement pattern obtained by combining these pixels 22 with PD and pixels 23 without PD is used as a failure-detection pattern.

In order to read the failure-detection pattern formed as described above, after a usual reading operation, in which image signals are read out for each frame from an entirety of the effective pixel area 3 shown in FIG. 1, and subsequently, the driving method is switched to a driving method different from that for reading image signals from the effective pixel area 3 (this driving method will be described later), so that a reading operation is performed. By so doing, a potential signal pattern corresponding to the foregoing failure-detection pattern is read out from the failure-detection pattern area 21. Thus, a signal corresponding to the specific arrangement pattern in the failure-detection pattern area 21 is checked at all the times, and when a signal corresponding to the specific arrangement pattern is not outputted, it is determined that a failure occurs.

It should be noted that in the above-described configuration, an operation of sequential reading in the row direction is assumed, and a specific one row is used as the failure-detection pattern area 21. The effect of the present invention, however, can be achieved in the same manner also in the case where the failure-detection pattern area 21 is disposed at an arbitrary position in the non-effective pixels; that is, the detection-failure pattern area 21 is not limited to a specific one row.

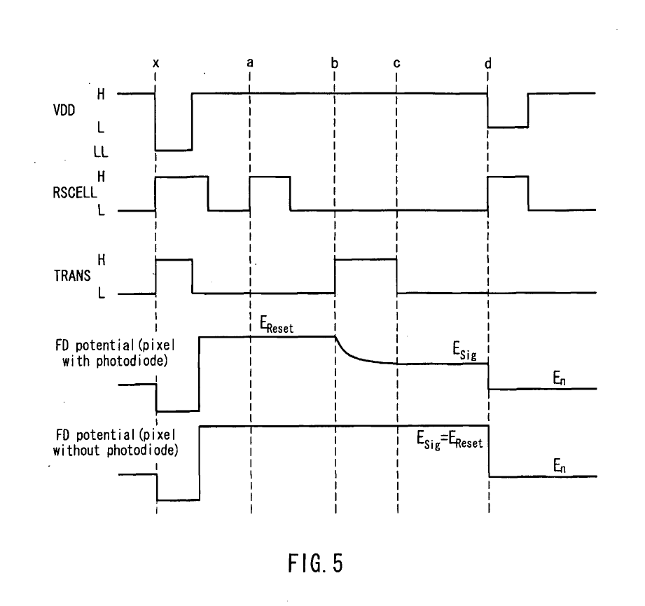

Next, an example of timings for driving pixel cells in the failure-detection pattern area 21 is described below, with reference to FIG. 5. A power source VDD line 19 and a reset signal line (RSCELL signal line) 17 are connected in the row direction commonly with all the pixel cells in the failure-detection pattern area 21, and a TRANS signal line 18 is connected in the row direction commonly with all the pixels with PD. When the failure detection pattern is read out, unlike a reading operation with respect to the pixel regions formed in the normal effective pixel area 3, charges are injected in the photodiodes 9 preliminarily, and thereafter a normal reading operation is performed, which is similar to the operation shown in FIG. 8. This driving method is described below step by step, with reference to FIG. 5.

First, a power source VDD supplied from the power source VDD line 19 is set to a low voltage LL that is lower than a usual low voltage L in a non-selection operation, and the reset transistor 13 (RSCELL) and the transfer gate 10 (TRANS) are controlled so as to be turned ON (timing (x)). With this, charges are injected into the photodiode 9 via the FD 11 from the power source VDD. Here, charges are accumulated in the photodiode in the pixel 22 with PD, whereas charges are not accumulated in the pixel 23 without PD. Next, the power source voltage VDD is turned back to a High level “H”, and the transfer gate 10 (TRANS) is controlled to be OFF, while continuously maintaining the reset transistor 13 (RSCELL) in the ON state, whereby the potential of the FD is set to Eᵣₑₛₑₜ (timing (a)).

In this state, when the transfer gate 10 (TRANS) is turned ON (timing (b)), the charges (electrons) accumulated in the photodiode 9 of the pixel cell 5 are transferred to the FD 11. Here, in the pixel 22 with PD, charges accumulated in the photodiode at the timing (x) are read out, whereby the potential of the FD 11 is reduced to E_{sig} at a timing (c). On the other hand, in the pixel 23 without PD, charges are not varied at all, so that the potential of the FD therefore do not vary, retaining Eᵣₑₛₑₜ.

In the foregoing manner, a signal corresponding to the array of the presence/absence of the photodiodes is outputted to the signal line 7 via the amplifier transistor 15 shown in FIGS. 7 and 4. Finally, the voltage of the power source VDD is caused to be reduced to a Low level “L”, and the reset transistor 13 (RSCELL) is controlled to be an ON state, whereby the potential of the FD 11 is caused to be reduced to Eₙ, to set to a non-selection state (timing (d)).

By the above-described driving method, the signals outputted from the pixels 22 with PD and the pixels 23 without PD to the vertical signal lines 7 are transferred to the signal processing area 4. Then, the presence/absence of a signal according to the arrangement of the pixels 22 with PD and the pixels 23 without PD in the row direction, outputted from the horizontal signal line 8, is checked for each frame. By so doing, even under dark conditions without incidence of external light, it is possible to check whether there is no incident light or a failure occurs, that is, whether the solid-state imaging device has a failure or not. Therefore, a mechanism for ensuring failsafe even when the solid-state imaging device has a failure can be obtained.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A solid-state imaging device, comprising:
an effective pixel area in which a plurality of pixels having photodiodes (PD) are provided in row and column directions, the effective pixel area being capable of allowing light from outside to be incident in each photodiode and generating electric signals by photoelectric conversion; and
a non-effective pixel area in which a plurality of pixels covered by a light-shielding film are provided, and a reference area and a failure-detection pattern area are formed as sub-areas,
wherein
each pixel in the reference area has a photodiode,
the failure-detection pattern area has a configuration such that pixels with PD in which a photodiode is provided and pixels without photodiodes in which a photodiode is not provided are combined into a predetermined arrangement pattern, and
the solid-state imaging device is configured so that each of pixels in the effective pixel area is driven so as to output a pixel signal, and each of pixels in the non-effective pixel area including the failure-detection pattern area also can be driven so as to output a pixel signal.

2. The solid-state imaging device according to claim 1, wherein the failure-detection pattern area is configured by arranging the pixels with PD and the pixels without PD in a row.

3. The solid-state imaging device according to claim 1, wherein
the pixel in the effective pixel area includes: the photodiode, which can carry out photoelectric conversion of incident light and accumulate charges obtained; a floating diffusion in which charges are temporarily accumulated; a transfer transistor that transfers charges in the photodiode to the floating diffusion; a reset transistor that resets charges in the floating diffusion; and an amplifier transistor that amplifies a potential of the floating diffusion,
the pixel disposed in the reference area and the pixel with PD disposed in the failure-detection pattern area have the same configuration as that of the pixel in the effective pixel area, and
the pixel without PD disposed in the failure-detection pattern area includes the floating diffusion, the reset transistor, and the amplifier transistor.

4. A method for driving the solid-state imaging device according to claim 1, comprising:
a step (1) of reading image signals from the pixels in the effective pixel area;
a step (2) of carrying out an operation for injecting charges from outside into the pixels in the failure-detection pattern area; and then
a step (3) of reading signals according to the injected charges from each of pixels in the failure-detection patter area.

5. The method for driving the solid-state imaging device according to claim 4, the method being for driving the solid-state imaging device in which
the photodiode, which can carry out photoelectric conversion of incident light and accumulate charges obtained; a floating diffusion in which charges are temporarily accumulated; a transfer transistor that transfers charges of the photodiode to the floating diffusion; a reset transistor that resets charges in the floating diffusion; and an amplifier transistor that amplifies a potential of the floating diffusion,
the pixel disposed in the reference area and the pixel with PD disposed in the failure-detection pattern area have the same configuration as that of the pixel in the effective pixel area, and
the pixel without PD disposed in the failure-detection pattern area includes the floating diffusion, the reset transistor, and the amplifier transistor,
wherein
the step (2) includes:
a sub-step (2a) of controlling the reset transistor and the transfer transistor of the pixels in the failure-detection pattern area to be an ON state so as to inject charges into the floating diffusion and the photodiode via the reset transistor and the transfer transistor with a power source voltage; and
a sub-step (2b) of controlling the transfer transistor to be OFF state and subsequently controlling the reset transistor to be ON state so as to reset a potential of the floating diffusion.

6. The method for driving the solid-state imaging device according to claim 5, wherein in the sub-step (2a), the power source voltage is lower than any voltage used when pixel signals are read from the effective pixel area.
